(19) United States
(12) Patent Application Publication
(10) Pub. No.: US 2026/0028749 A1
(43) Pub. Date: Jan. 29, 2026

(54) APPARATUS FOR PRODUCING GROUP III NITRIDE CRYSTAL

(71) Applicant: PANASONIC HOLDINGS CORPORATION, Osaka (JP)

(72) Inventors: Junichi Takino, Osaka (JP); Masayuki Hoteida, Osaka (JP); Shunichi Matsuno, Kyoto (JP)

(21) Appl. No.: 19/349,002

(22) Filed: Oct. 3, 2025

Related U.S. Application Data
(63) Continuation of application No. PCT/JP2024/005816, filed on Feb. 19, 2024.

(30) Foreign Application Priority Data
Apr. 13, 2023 (JP) 2023-065654

(51) Int. Cl. C30B 25/08; C30B 25/10; C30B 25/14; C30B 29/40

(52) U.S. Cl. CPC C30B 25/08; C30B 25/10; C30B 25/14; C30B 29/406

(57) ABSTRACT

An apparatus according to one aspect of the present disclosure includes: a starting material chamber including a group III element source and the starting material chamber being configured to supply a group III element oxide gas; and at least two gas supply pipes connected to the starting material chamber. An oxidizing gas and a reducing gas are separately supplied to the starting material chamber via the gas supply pipes and react with each other in the starting material chamber to generate a reactive gas. The generated reactive gas reacts with the group III element source to generate the group III element oxide gas.

### CROSS REFERENCE TO RELATED APPLICATION

This is a continuation application of International Application No. PCT/JP2024/005816 with an international filing date of Feb. 19, 2024, which claims priority of Japanese Patent Application No. 2023-065654 filed on Apr. 13, 2023, the content of which is incorporated herein by reference.

### BACKGROUND

### Technical Field

The present disclosure relates to an apparatus for producing a group III nitride crystal, and more particularly, to an apparatus for producing a group III nitride crystal by the vapor phase epitaxy method.

### BACKGROUND ART

Group III nitride crystals such as GaN are expected to be applied to next-generation optical devices such as high-output light-emitting diodes (LEDs) and laser diodes (LDs), and next-generation electronic devices such as high-output power transistors mounted on such as electric vehicles (EVs) and plug-in hybrid vehicles (PHVs). As a method for producing group III nitride crystals, the oxide vapor phase epitaxy (OVPE) method using group III oxides as starting materials is used (see, e.g., WO 2015053341).

An example of a reaction scheme in the OVPE method is as follows. An H₂O gas is introduced while Ga is heated. The introduced H₂O gas reacts with Ga to generate a Ga₂O gas (formula (1) below). Then, an NH₃ gas is introduced and reacted with the generated Ga₂O gas to generate GaN crystals on a seed substrate (formula (2) below).

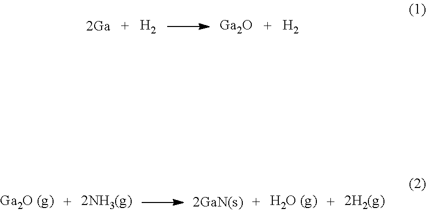

In the producing method described in WO 2015053341, in order to stabilize the generation amount of group III element oxide gas for producing group III nitride crystals, H₂O gas needs to be supplied at a constant supply rate. In the producing process, for example, such like bubbling method can be used to supply the H₂O gas. In the bubbling method, to maintain a stable H₂O gas supply, the temperature of the entire thermostatic chamber in which liquid H₂O is stored needs to be precisely controlled.

Temperature control of the thermostatic chamber for liquid H₂O used in group III nitride crystal producing process is described here with reference to FIGS. 1A and 1B. FIG. 1A is a graph showing a relationship between the saturated vapor pressure of H₂O and the temperature of the thermostatic chamber for liquid H₂O, and FIG. 1B is a graph showing a relationship between the H₂O gas supply rate and the temperature of the thermostatic chamber, in a case that N₂ is supplied as carrier gas at 0.5 L/min during the H₂O gas introduction. As shown in FIG. 1A, the saturated vapor pressure of H₂O varies depending on the temperature of the thermostatic chamber for liquid H₂O. Hence, as shown in FIG. 1B, the H₂O gas supply rate varies depending on the temperature of the thermostatic chamber, and the larger the amount of H₂O gas supplied, the more the H₂O gas supply rate is affected by fluctuations in the temperature of the thermostatic chamber.

For example, if intend to supply H₂O gas at 360 mL/min with an accuracy of ±1% of supply error, the temperature of the entire thermostatic chamber needs to be controlled within ±0.3° C. When aiming for larger GaN crystal to be grown, the supply amount of the starting material Ga₂O gas is also increased (see formula (2)). In such a case, to increase the supply amount of the H₂O gas, an increased capacity of the thermostatic chamber for the liquid H₂O gas is required. For example, to grow a GaN crystal with a thickness of 10 mm and a diameter of 6 inches, 868 mL of liquid H₂O is required, assuming a reaction rate between Ga and H₂O is 36.6% and a Ga yield in the GaN crystal growth is 37.1%. To store 868 mL of liquid H₂O, for example, a thermostatic chamber with a bottom surface of 78.54 cm² and a height of 11.1 cm or more is required. Controlling the temperature of liquid H₂O in a thermostatic chamber of such a size within ±0.3° C. would be highly difficult.

In producing group III nitride crystals, it is difficult to control the temperature of the thermostatic chamber for liquid H₂O with high precision, making it difficult to stabilize the generation amount of the group III element oxide gas. As a result, there is a problem in ensuring the stability of the quality of GaN crystals to be grown.

### SUMMARY

Thus, an object of the present disclosure is to solve the above conventional problem and to provide an apparatus for producing group III nitride crystals that can facilitate stabilizing the generation amount of group III oxide gas in producing group III nitride crystals.

In order to address the issue described above, the present disclosure provides an apparatus for producing a group III nitride crystal. An apparatus according to one aspect of the present disclosure includes: a starting material chamber including a group III element source and the starting material chamber being configured to supply a group III element oxide gas; and at least two gas supply pipes connected to the starting material chamber. An oxidizing gas and a reducing gas are separately supplied to the starting material chamber via the gas supply pipes and react with each other in the starting material chamber to generate a reactive gas. The generated reactive gas reacts with the group III element source to generate the group III element oxide gas.

According to the apparatus of one aspect of the present disclosure, stabilization of the group III oxide gas production can be facilitated in producing group III nitride crystals.

### BRIEF DESCRIPTION OF DRAWINGS

FIG. 1A is a graph showing a relationship between the saturated vapor pressure of H₂O and the temperature of a thermostatic chamber for liquid H₂O;

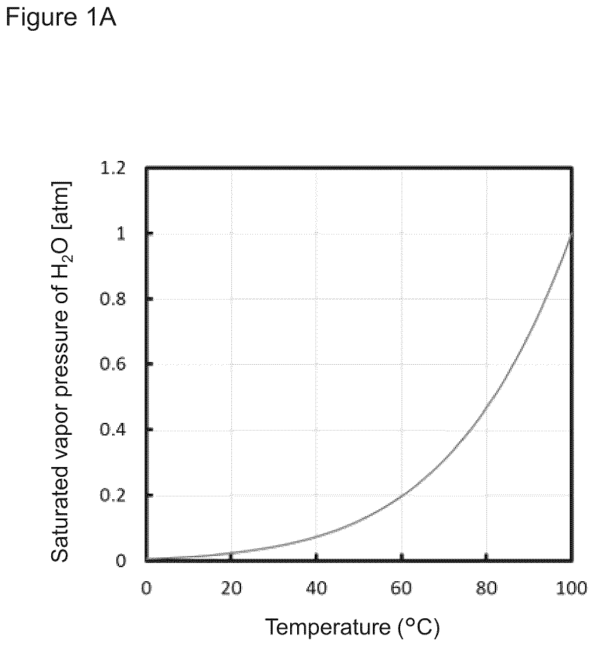

FIG. 1B is a graph showing a relationship between the H₂O gas supply rate and the temperature of the thermostatic chamber when N₂ is supplied as a career gas at 0.5 L/min during the H₂O gas introduction;

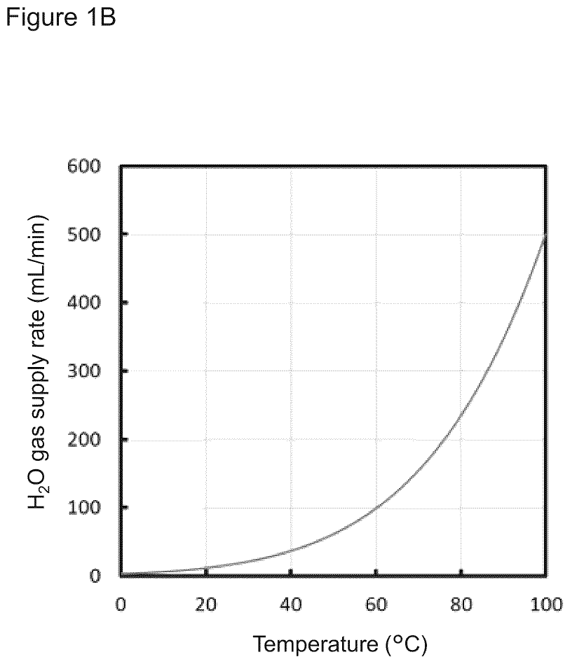

FIG. 2 is a schematic partial cross-sectional view showing an example of a configuration of an apparatus for producing group III nitride crystals according to an embodiment of the present disclosure;

FIG. 3 is a schematic partial cross-sectional view showing another example of a configuration of a starting material chamber of the apparatus of FIG. 2;

FIG. 4 is a schematic partial cross-sectional view showing a still another example of a configuration of the starting material chamber of the apparatus of FIG. 2;

FIG. 5 is a schematic partial cross-sectional view showing a further example of a configuration of the starting material chamber of the apparatus of FIG. 2;

FIG. 6 is a flowchart showing an example of a group III nitride crystal producing process using the apparatus according to the embodiment of the present disclosure;

FIG. 7 is a flowchart showing operations of the apparatus at a growth step of the producing process of FIG. 6;

FIG. 8 is a table 1 showing an evaluation of the group III nitride crystal growth in Examples and in Comparative Examples according to the embodiment of the present disclosure;

FIG. 9 is a graph showing an evaluation of growth rates of the group III nitride crystals in the Examples and in the Comparative Examples according to the embodiment of the present disclosure; and

FIG. 10 is a graph showing an evaluation of crystallinity of the group III nitride crystals in the Examples and in the Comparative Examples according to the embodiment of the present disclosure.

### DETAILED DESCRIPTION

An apparatus for producing a group III nitride crystal according to one aspect of the present disclosure includes: a starting material chamber including a group III element source and the starting material chamber being configured to supply a group III element oxide gas; and at least two gas supply pipes connected to the starting material chamber. An oxidizing gas and a reducing gas are separately supplied to the starting material chamber via the gas supply pipes and react with each other in the starting material chamber to generate a reactive gas. The generated reactive gas reacts with the group III element source to generate the group III element oxide gas.

According to this aspect, stabilization of the group III oxide gas production can be facilitated in producing group III nitride crystals.

In addition, in an apparatus according to another aspect of the present disclosure, the starting material chamber includes: a reactive gas generation section located upstream; and a reaction section located downstream and configured to be in fluid communication with the reactive gas generation section. The gas supply pipes are connected to the reactive gas generation section, and the group III element source is disposed inside the reaction section.

In addition, in an apparatus according to another aspect of the present disclosure, the reactive gas generation section and the reaction section are separated by a partition plate.

In addition, in an apparatus according to another aspect of the present disclosure, the reactive gas generation section includes at least one reflector plate.

In addition, in an apparatus according to another aspect of the present disclosure, the partition plate includes at least one reflector plate.

In addition, in an apparatus according to another aspect of the present disclosure, the starting material chamber has a cylindrical shape with at least one connection port disposed on a side wall, and the at least one gas supply pipe is connected to the starting material chamber via the connection port.

In addition, in an apparatus according to another aspect of the present disclosure, a plurality of connection ports are circumferentially arranged on the side wall with a uniform interval.

In addition, in an apparatus according to another aspect of the present disclosure, the starting material chamber includes at least one material selected from a group consisting of quartz, carbon, PG, PBN, SiC, transition metal, and stainless steel.

In addition, in an apparatus according to another aspect of the present disclosure, the gas supply pipe includes at least one material selected from a group consisting of quartz, carbon, PG, PBN, SiC, transition metal, and stainless steel.

In addition, an apparatus according to another aspect of the present disclosure further includes a heating section. The heating section is configured to keep a temperature of the reactive gas generation section at 290° C. or higher, and to keep a temperature of the reaction section at 800° C. or higher and lower than 1800° C.

In addition, an apparatus according to another aspect of the present disclosure further includes a seed substrate. A group III nitride crystal is generated on the seed substrate, and the heating section is configured to keep a temperature of the seed substrate at a temperature higher than that of the reaction section.

In addition, a method for producing a group III nitride crystal according to another aspect of the present disclosure includes: separately supplying an oxidizing gas and a reducing gas; generating a reactive gas by reacting the supplied oxidizing gas with the supplied reducing gas; generating a group III element oxide gas by reacting the generated reactive gas with a group III element source; and generating a group III nitride crystal by reacting the generated group III element oxide gas with a nitrogen element-containing gas.

Any of the above various embodiments may be appropriately combined to achieve effects of the embodiments.

An embodiment will now be described in detail with reference to the drawings as appropriate. However, more detailed explanation than necessary may be omitted. For example, detailed explanation of well-known matters or duplicate explanation of substantially the same configuration may be omitted. This is to avoid the following explanation becoming unnecessarily redundant and to facilitate understanding by those skilled in the art.

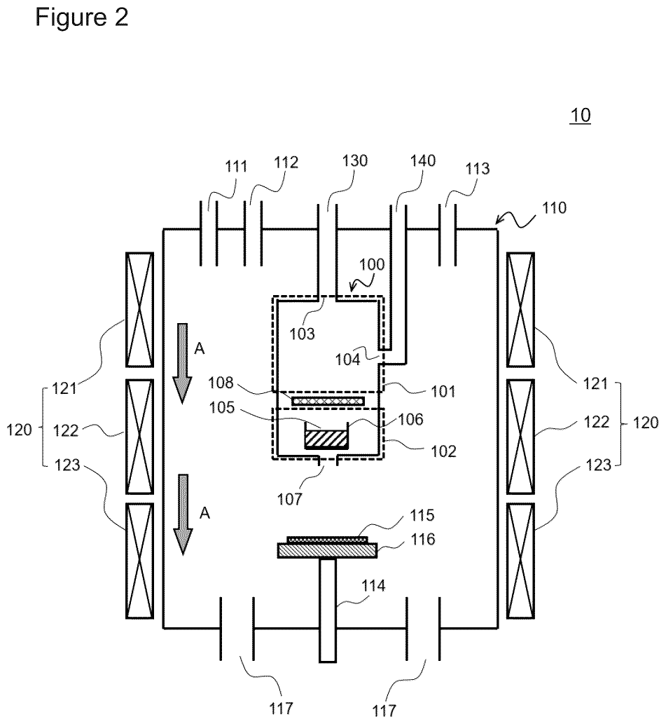

A flow synthesis apparatus according to an embodiment of the present disclosure will be described with reference to FIGS. 2 to 9. The accompanying drawings and the following description are provided for allowing those skilled in the art to fully understand the present disclosure, and are not intended to limit the subject matter described in the scope of claims. In the figures, elements are shown exaggerated for ease of description. In the figures, the same reference numerals are imparted to substantially the same components.

### EMBODIMENT

### <Configuration of an Apparatus for Producing Group III Nitride Crystals>

FIG. 2 is a schematic partial cross-sectional view showing an example of a configuration of an apparatus 10 for producing group III nitride crystals according to an embodiment of the present disclosure. The apparatus 10 shown in FIG. 2 includes a starting material chamber 100, a growing chamber 110, a heating section 120, and gas supply pipes 130, 140. The apparatus 10 can be used to produce group III nitride crystals by the vapor phase epitaxy method. FIG. 2 is a schematic view, and the sizes, ratios, etc. of the constituent members may differ from the actual ones.

In this embodiment, the starting material chamber 100 and growing chamber 110 of the apparatus 10 can each be configured in a cylindrical shape. The starting material chamber 100 is disposed inside the growing chamber 110 and is in fluid communication with the growing chamber 110 at a gas supply port 107. Gas in the apparatus 10 flows from the upstream side to the downstream side in the flow direction A shown in the figure. The heating section 120 includes heaters 121, 122, and 123 arranged around the periphery of the growing chamber 110 to maintain temperatures inside the starting material chamber 100 and the growing chamber 110.

A group III element source 105 is disposed in the starting material chamber 100, and the gas supply pipes 130 and 140 are connected to the starting material chamber 100 on the upstream side of the group III element source 105. In this embodiment, an oxidizing gas and a reducing gas are separately supplied to the starting material chamber 100 via the gas supply pipes 130 and 140, reacting each other within the starting material chamber 100 to generate a reactive gas. The generated reactive gas reacts with the group III element source to generate a group III element oxide gas, and the generated group III element oxide gas is supplied to the growing chamber 110 via the gas supply port 107. The configuration of the starting material chamber 100 will be described in more detail later.

A seed substrate 115 and a substrate susceptor 116 that holds the seed substrate 115 are located in the growing chamber 110. In this embodiment, both the seed substrate 115 and the substrate susceptor 116 are circular and arranged downstream of the gas supply port 107 of the starting material chamber 100. The substrate susceptor 116 is connected to a rotating shaft 114 and can rotate together with the seed substrate 115 during group III nitride crystal growth, driven by the rotating shaft 114.

At an upper part of the growing chamber 110, a nitrogen-containing gas is introduced into the growing chamber 110 via a nitrogen-containing gas supply port 111. A carrier gas for the nitrogen-containing gas is introduced via carrier gas supply ports 112 and 113. The carrier gas may be, but is not limited to, an inert gas such as Ar or N₂. In the growing chamber 110, the introduced nitrogen-containing gas reacts with the group III element oxide gas supplied from the starting material chamber 100, thereby obtaining group III nitride crystals on the seed substrate 115. The starting material gas including the unreacted group III element oxide gas and nitrogen-containing gas, as well as the carrier gas such as Ar or N₂ are exhausted from an exhaust port 117 disposed at the bottom of the growing chamber 110.

### <Configuration of Starting Material Chamber 100>

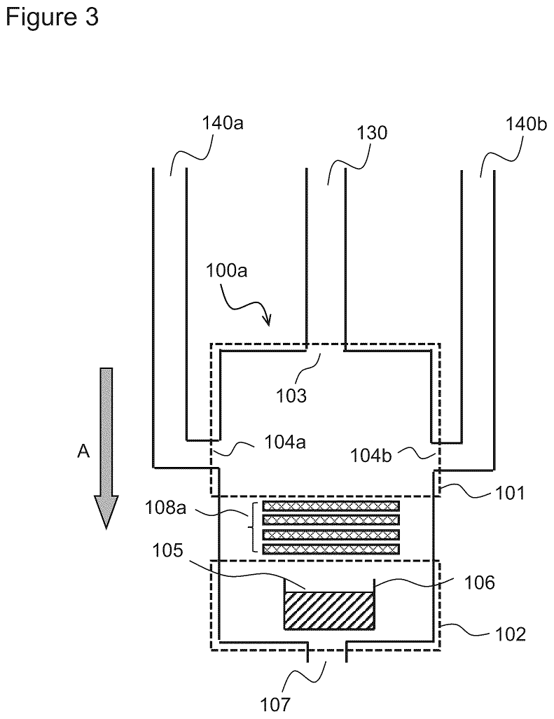

The configuration of the starting material chamber 100 according to this embodiment will be described with reference to FIGS. 3 to 5, together with FIG. 2. FIGS. 3 to 5 are schematic partial cross-sectional views each showing another example of the configuration of the starting material chamber of the apparatus 10 in FIG. 2, and are schematic partial cross-sectional views showing configurations of starting material chambers 100a, 100b, and 100c, respectively. In FIGS. 2 to 5, the same or similar components are given the same reference numerals, and detailed description thereof will be omitted.

The starting material chamber 100 shown in FIG. 2 includes a reactive gas generation section 101 positioned upstream, and a reaction section 102 positioned downstream in fluid communication with the reactive gas generation section 101. Connection ports 103 and 104 are located in the reactive gas generation section 101, and the gas supply pipes 130 and 140 are connected to the starting material chamber 100 via the connection ports 103 and 104, respectively. A starting material boat 106 is disposed in the reaction section 102, and the group III element source 105 is placed on the starting material boat 106. In this embodiment, the group III source 105 is a Ga source.

The starting material boat 106 in the reaction section 102 can be configured in a shape that can increase a contact area between the reactive gas and the group III element source 105. The starting material boat 106 can be configured, for example, in a multi-stage dish shape, to prevent the reactive gas from passing through the reaction section 102 without coming into contact with the group III element source 105.

In this embodiment, the reactive gas generation section 101 and reaction section 102 of the starting material chamber 100 are separated from each other by a partition plate 108. In the reactive gas generation section 101, the reducing gas and oxidizing gas introduced separately via the gas supply pipes 130 and 140 react with each other to generate the reactive gas. As shown, openings through which the gas flows are formed around the partition plate 108, and the generated reactive gas flows into the reaction section 102 through the openings, and reacts with the group III element source in the reaction section 102 to generate the group III element oxide gas. In this embodiment, H₂ gas is used as the reducing gas, and O₂ gas is used as the oxidizing gas. H₂O gas, which is the reactive gas, is generated in the reactive gas generation section 101, and Ga₂O gas, which is a group III element oxide gas, is generated in the reaction section 102.

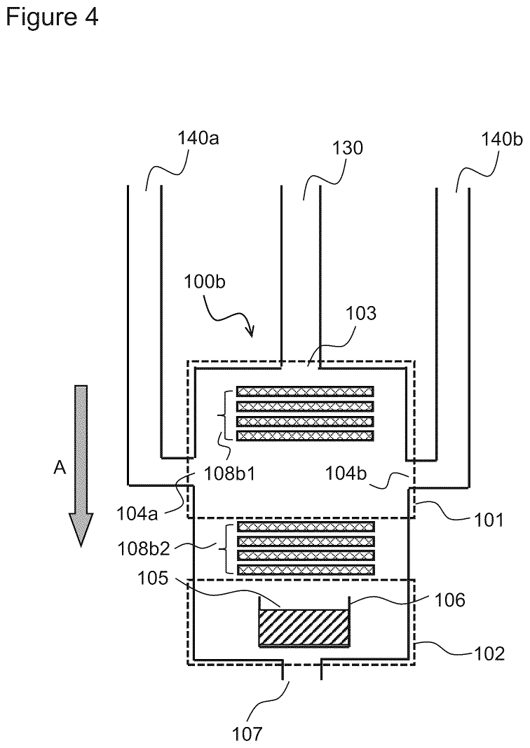

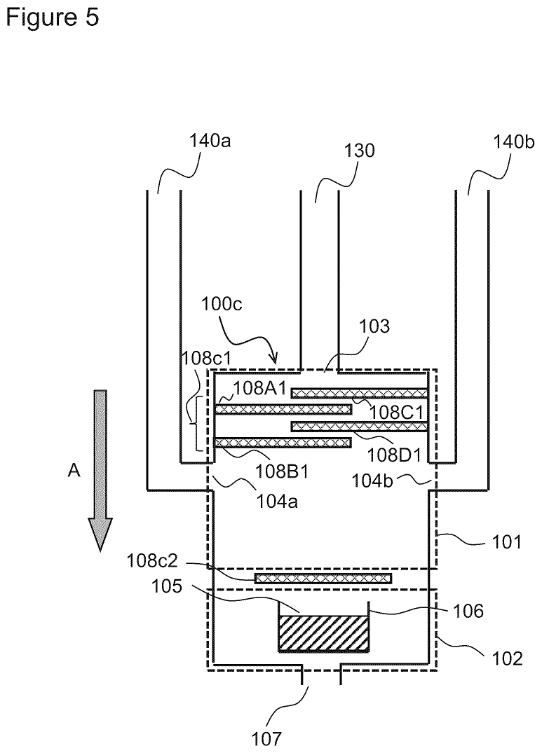

In this embodiment, the partition plate 108 may include at least one reflector plate. The partition plate 108 may include one or more reflector plates. Further, at least one reflector plate can be disposed inside the reactive gas generation section 101. For example, a partition plate 108a including a plurality of reflector plates is positioned in the configuration example of the starting material chamber 100a shown in FIG. 3. In the configuration example of the starting material chamber 100b shown in FIG. 4, a plurality of reflector plates 108b1 are disposed in the center of the starting material chamber 100, inside the reactive gas generation section 101, and a plurality of reflector plates 108b2 served as partition plates are positioned between the reactive gas generation section 101 and the reaction section 102. In the configuration example of the starting material chamber 100c shown in FIG. 5, a plurality of reflector plates 108c1 inside the reactive gas generation section 101 and a reflector plate 108c2 as the partition plate are disposed. The reflector plates 108c1 are configured so that the first ends of the individual reflector plates 108A1, 108B1, 108C1, and 108D1 are arranged along the inner wall of the starting material chamber 100, and the second ends of the individual reflector plates 108A1, 108B1, 108C1, and 108D1 are alternately staggered.

By disposing the partition plate between the reactive gas generation section 101 and the reaction section 102, and/or disposing the at least one reflector plate inside the reactive gas generation section 101, convection flow between the reducing gas and the oxidizing gas introduced into the reactive gas generation section 101 can be easily formed, thereby improving reaction efficiency. The shape, dimensions, or installation position of the one or more partition plates or the one or more reflector plates inside the reactive gas generation section can be designed according to the intended uses, and the present disclosure is not limited thereto.

In this embodiment, as shown in FIG. 2, connection ports 103 and 104 of the gas supply pipes 130 and 140 are respectively installed on the end wall and the side wall of the starting material chamber 100, although the present disclosure is not limited thereto. The connection ports 103 and 104 of the gas supply pipes 130 and 140 may both be installed either on the end wall or the side wall of the starting material chamber 100. The reducing gas and the oxidizing gas are supplied to the reactive gas generation section separately via the gas supply pipes 130 and 140. This prevents the reducing gas and the oxidizing gas from reacting with each other inside the gas supply pipes, and avoids damage to the pipes or the chamber by a chain of reactions occurring on the upstream side of the supply, caused by the heat generated from the reaction of the reducing gas and the oxidizing gas.

Additionally, by installing the oxidizing gas supply pipe and the reducing gas supply pipe apart from each other, backflow of the oxidizing gas into the reducing gas supply pipe or backflow of the reducing gas into the oxidizing gas supply pipe can be prevented. To prevent the backflow of the reducing gas or the oxidizing gas, for example, a check valve structure (not shown) may be provided in the gas supply pipes 130 and 140.

The present disclosure is not limited to cases where two gas supply pipes are disposed. For example, two or more oxidizing gas supply pipes and/or two or more reducing gas supply pipes can be disposed. As shown in FIGS. 3 to 5, connection ports 104a and 104b for the gas supply pipes 140a and 140b are provided on the side wall of the starting material chamber. A plurality of the connection ports can be provided on the side wall of the cylindrical starting material chamber and the plurality of the connection ports can be circumferentially arranged on the side wall with a uniform interval. This allows for more uniform production of the reactive gas. Further, multiple connection ports can be configured to be circumferentially and symmetrically arranged on the side wall of the starting material chamber. The present disclosure does not specify the pipe for the oxidizing gas supply or that for the reducing gas supply, and either gas supply pipes 130 and 140 can be used as the oxidizing gas supply pipe while the other can be used as the reducing gas supply pipe.

In this embodiment, the starting material chamber 100, the partition plate 108 and the reflector plate, and the gas supply pipes 130, 140 may include at least one material selected from a group consisting of quartz, carbon, PG, PBN, SiC, transition metals, and stainless steel.

### <Function of Heating Section 120>

In this embodiment, the reactive gas generation section 101 in the starting material chamber 100 is heated by a first heater 121 and second heater 122 of the heating section 120. H₂ gas is used as the reducing gas and O₂ gas is used as the oxidizing gas. Considering the ignition points of H₂ and O₂ gases, the temperature of the reactive gas generation section 101 can be maintained at 290° C. or higher.

In this embodiment, the reaction section 102 is heated by the first heater 121 and second heater 122 of the heating section 120. The temperature of the reaction section 102 can be maintained at 800° C. or higher, which is above the boiling point of the group III element oxide gas such like GaO₂ gas to be generated in the reaction section 102. If the temperature of the group III oxide gas supply port 107 is higher than that of the seed substrate 115, a reverse reaction in a process of producing the group III oxide gas occurs, and the group III element source 105 may precipitate on the seed substrate 115. Therefore, the temperature of the reaction section 102 can be maintained at a lower level than that of the seed substrate 115 by utilizing the first heater 121 and second heater 122 of the heating section 120. As described later, in cases that the temperature of the seed substrate 115 is maintained at 1800° C. or lower by a third heater 123 of the heating section 120, the temperature of the reaction section 102 can be set to, for example, less than 1800° C.

In this embodiment, the seed substrate 115 is heated using the third heater 123 of the heating section 120. As described above, to prevent the reverse reaction in the process of producing the group III element oxide gas, the temperature of the seed substrate 115 can be controlled to maintain not lower than the temperature of the reaction section 102 and that of the group III oxide gas supply port 107. In this embodiment, the temperature of the seed substrate 115 can be maintained between 1000° C. and 1800° C. by using the third heater 123.

In the apparatus 10 configured in this manner, in cases that the reducing gas and the oxidizing gas are supplied via, for example, a mass flow controller, a stable supply with a supply fluctuation of less than 1% is possible. Hence, the amount of the reactive gas produced can be stabilizes, facilitating stabilization of the amount of the group III element oxide gas. This allows the growth rate of group III nitride crystal to remain constant, and group III nitride crystals can be produced with high quality stability. Further, a thermostatic chamber or a liquid H₂O filling container used in the bubbling method is no longer necessary, and group III nitride crystals can be produced using a simple apparatus. Moreover, precise temperature control for the thermostatic chamber is also unnecessary, and the producing process is simplified.

### <Group III Nitride Crystal Producing Process>

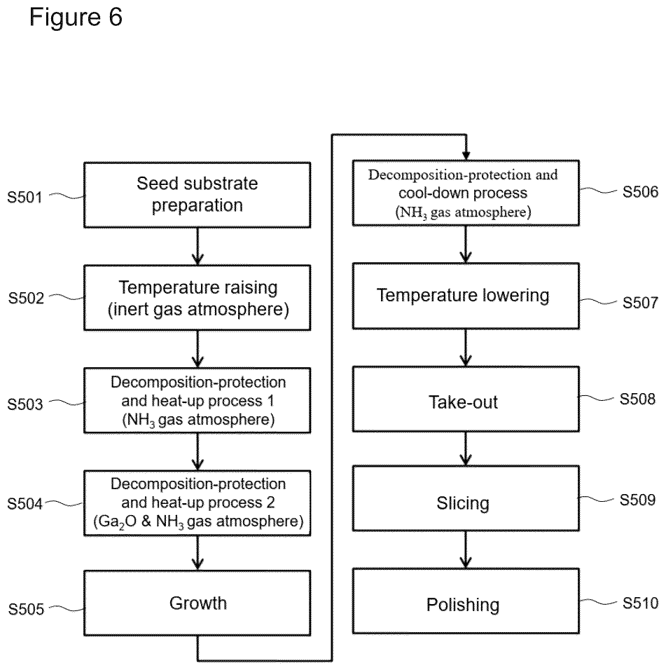

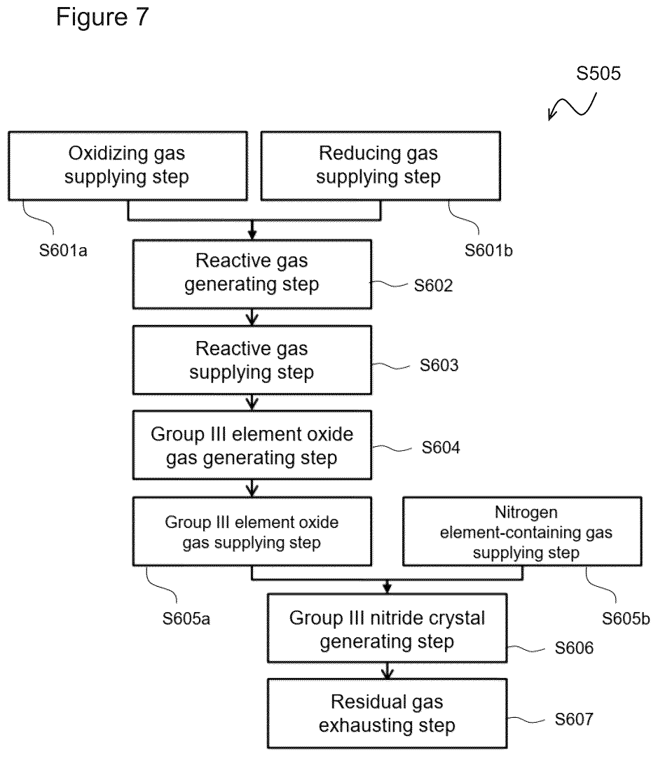

A process for producing group III nitride crystals will be described with reference to FIGS. 6 and 7. FIG. 6 is a flowchart showing one example of a process for producing group III nitride crystals using the apparatus 10 according to the embodiment of the present disclosure. FIG. 7 is a flowchart showing operations of the apparatus 10 at a growth step of the producing process of FIG. 6.

As shown in FIG. 6, group III nitride crystal producing process may include steps S501 to S510. Each step will be described below.

At a seed substrate preparation step S501, the seed substrate 115 is placed on the substrate susceptor 116.

At a temperature raising step S502, the seed substrate 115 is heated to a temperature of 100° C. or higher and lower than 500° C. in an inert gas atmosphere.

At a first decomposition-protection and heat-up step S503, the seed substrate 115 is heated to a temperature of 500° C. or higher and lower than 1100° C. in an NH₃ gas atmosphere.

At a second decomposition-protection and heat-up step S504, the seed substrate 115 is further heated to a temperature of 1100° C. or higher and lower than 1500° C. in a Ga₂O and NH₃ gas atmosphere. An atmosphere with only NH₃ gas may cause decomposition of group III nitride crystals. Therefore, Ga₂O gas is introduced together with NH₃ gas in the heat-up process 2 to suppress decomposition under the high-temperature environment in which group III nitride crystals are grown.

A growth process S505 will be described with reference to FIG. 7. At the growth step S505, group III nitride crystals are generated on the seed substrate 115, using the apparatus 10 according to the embodiment of the present disclosure. As shown in FIG. 7, group III nitride crystal growth process S505 may include steps S601a to S607. The steps included in the growth process S505 may be performed substantially simultaneously in the apparatus 10.

### (Group III Nitride Crystal Growth Process)

In this embodiment, metallic Ga is used as the starting group III element source 105.

(1) At an oxidizing gas supplying step S601a, the oxidizing gas is supplied to the reactive gas generation section 101 of the starting material chamber 100 via the oxidizing gas supply pipe. The oxidizing gas supply pipe may be the gas supply pipe 130 connected to the connection port 103 disposed on end wall of the starting material chamber 100, or may be a gas supply pipe 140 connected to a connection port 104 disposed on the side wall of the starting material chamber 100 (see FIG. 2).

In this embodiment, the O₂ gas is used as the oxidizing gas. Other than the O₂ gas, for example, CO gas, CO₂ gas, NO gas, N₂O gas, NO₂ gas, and N₂O₄ gas may be used as the oxidizing gas.

(2) At a reducing gas supplying step S601b, the reducing gas is supplied to the reactive gas generation section 101 of the starting material chamber 100 via the reducing gas supply pipe. The reducing gas supply pipe may be the gas supply pipe 130 or the gas supply pipe 140 (see FIG. 2).

In this embodiment, the H₂ gas is used as the reducing gas. Other than the H₂ gas, for example, CH₄ gas, C₂H₄ gas, C₂H₆ gas, C₃H₆ gas, C₃H₈ gas, and C₄H₁₀ gas may be used as the reducing gas.

As a carrier gas for the oxidizing and reducing gases, the inert gas can be introduced into the reactive gas generation section 101. In this embodiment, for example, the N₂ gas can be introduced into the reactive gas generation section 101 as the carrier gas.

(3) At a reactive gas generating step S602, within the reactive gas generation section 101, the oxidizing and reducing gases supplied via the gas supply pipes 103 and 104 are mixed to react with each other, thereby generating the reactive gas.

In this embodiment, the O₂ gas, which is the oxidizing gas, reacts with the H₂ gas, which is the reducing gas, to generate the reactive gas H₂O gas. The reactive gas generation section 101 is maintained at a temperature of 290° C. or higher by the first heater 121 and second heater 122 of the heating section 120.

(4) At a reactive gas supplying step S603, the reactive gas is supplied from the reactive gas generation section 101 to the reaction section 102. In this embodiment, the H₂O gas generated in the reactive gas generation section 101 is fed to the reaction section 102 through openings around the partition plate 108.

(5) At a group III element oxide gas generating step S604, the reactive gas fed from the reactive gas generation section 101 reacts with the starting group III element source 105 inside the reaction section 102, thereby generating the group III element oxide gas.

In this embodiment, the H₂O gas as the reactive gas reacts with Ga, which is the starting group III element source 105, to generate the group III element oxide gas Ga₂O gas (formula (1)). The reaction section 102 is maintained by the first heater 121 and the second heater 122 of the heating section 120 so that the temperature is 800° C. or higher, which is above the boiling point of Ga₂O gas.

(6) At a group III element oxide gas supplying step S605a, the group III element oxide gas generated at the step S604 is supplied to the growing chamber 110.

In this embodiment, the Ga₂O gas generated in the reaction section 102 is supplied to the growing chamber 110 via the gas supply port 107. The seed substrate 115 is heated by the third heater 123 of the heating section 120, and the temperature of the seed substrate 115 is maintained not lower than the temperature of the reaction section 102 and that of the gas supply port 107 to prevent a reverse reaction of the reaction to generate the group III oxide gas Ga₂O gas.

(7) At a nitrogen element-containing gas supplying step S605b, nitrogen element-containing gas is supplied to the growing chamber 110 via a nitrogen-containing gas supply port 111. The carrier gas used in the nitrogen-containing gas supplying step is introduced via the carrier gas supply ports 112 and 113 (see FIG. 2).

In this embodiment, the NH₃ gas is used as the nitrogen-containing gas. In addition to the NH₃ gas, for example, NO gas, NO₂ gas, N₂O gas, N₂O₄ gas, N₂H₂ gas, N₂H₄ gas, and HCN gas may be used as the nitrogen-containing gas.

(8) At a group III nitride crystal generating step S606, inside the growing chamber 110, the group III element oxide gas supplied at the step S605a reacts with the nitrogen element-containing gas supplied at the step S605b, thereby group III nitride crystals are generated, growing on the seed substrate 115. The growing chamber 110 is heated by the heating section 120 to a temperature that may facilitate reaction of the group III element oxide gas and the nitrogen element-containing gas.

In this embodiment, the Ga₂O gas, which is the group III element oxide gas, reacts with NH₃ gas, which is the nitrogen-containing gas to grow the group III nitride crystal GaN on the seed substrate 115 (formula (2)). The seed substrate 115 in the growing chamber 110 is maintained at a temperature between 1000° C. and 1800° C. by the third heater 123 of the heating section 120.

(9) At a residual gas exhausting step S607, carrier gases that do not contribute to the growth of the group III nitride crystal and unreacted gases are exhausted from the exhaust port 117.

With the above steps, the growth process S505 is completed, and the producing process returns to FIG. 6, proceeding to a decomposition-protection and cool-down step S506. At the step S506, the seed substrate 115 is cooled down to a temperature of 800° C. or lower in the NH₃ gas atmosphere. Then, the temperature of the group III nitride crystal on the seed substrate 115 is further decreased to room temperature in the temperature lowering step S507.

The group III nitride crystal, which has been cooled down to the room temperature, undergoes a take-out step S508, a slicing step S509, and a polishing step S510 before being made into products. Conventionally known methods can be used for these steps, and thus, detailed explanations are omitted here.

With the above steps, group III nitride crystals can be produced. The above method for producing group III nitride crystals is merely an example, and method for producing group III nitride crystals is not limited to the above. The materials or fabrication conditions used in the above group III nitride crystal GaN growth process S505 are also an example, and are not limited to those described above.

### Examples and Comparative Examples

Group III nitride crystal growth was carried out using the apparatus 10 according to the embodiment of the present disclosure. Examples 1 to 3 and Comparative Examples 1 to 3 according to the embodiment of the present disclosure will be described below.

In Examples 1 to 3 and Comparative Examples 1 to 3, group III nitride crystal GaN was grown. Liquid Ga was used as the starting Ga source and the reaction between liquid Ga and the reactive gas H₂O gas was carried out, and the generated Ga₂O gas was used as the group III element oxide gas. GaN crystal growth was carried out so that the GaN crystals had a thickness of about 0.5 to 1.5 mm in a single growth. A target value of the growth rate was set at 200 m/h. The growth rate of the GaN crystals and quality of the generated GaN crystals were measured in cases that the reactive gas, H₂O gas, was generated in the apparatus 10 by synthesizing H₂ gas and O₂ gas (Examples 1 to 3) and that the reactive gas H₂O gas, was supplied into the apparatus 10 by the bubbling method (Comparative Examples 1 to 3), respectively.

### Examples 1 to 3

In Examples 1 to 3, the temperature of the reaction section was set to 1030° C., and the surface temperature of the seed substrate was set to 1150° C. The reducing gas H₂ gas was supplied at 27 L/min, the oxidizing gas O₂ gas was supplied at 0.18 L/min, and the carrier gas N₂ gas was supplied at 0.5 L/min to the reactive gas generation section of the starting material chamber to generate the reactive gas H₂O gas. The nitrogen-containing gas NH₃ gas was supplied to the growing chamber at 5 L/min. Growth time of the GaN crystal was set to 150 minutes in Example 1, 300 minutes in Example 2, and 450 minutes in Example 3, respectively.

### Comparative Examples 1 to 3

In Comparative Examples 1 to 3, the temperature of the reaction section and the surface temperature of the seed substrate were set to 1030° C. and 1150° C., respectively, the same as that in the Examples. The reactive H₂O gas was supplied to the starting material chamber at 0.36 L/min by bubbling with H₂ gas at 26.64 L/min and N₂ gas at 0.5 L/min. The nitrogen-containing gas NH₃ gas was supplied to the growing chamber at 5 L/min. The growth time of the GaN crystal was 150 minutes in Comparative Example 1, 300 minutes in Comparative Example 2, and 450 minutes in Comparative Example 3, respectively.

### (Evaluation of Group III Nitride Crystal Growth in Examples and Comparative Examples)

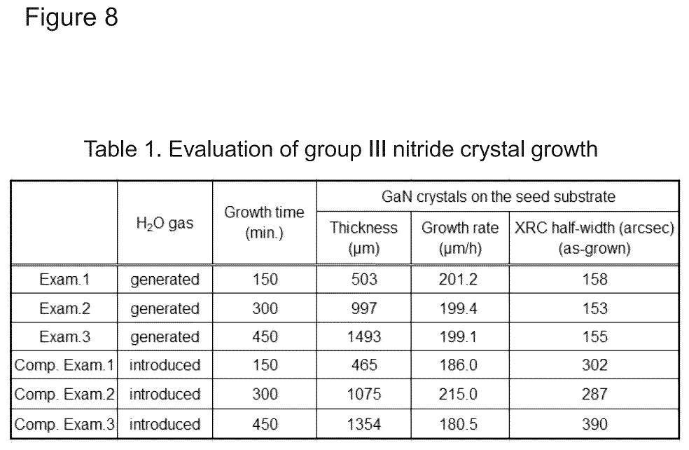

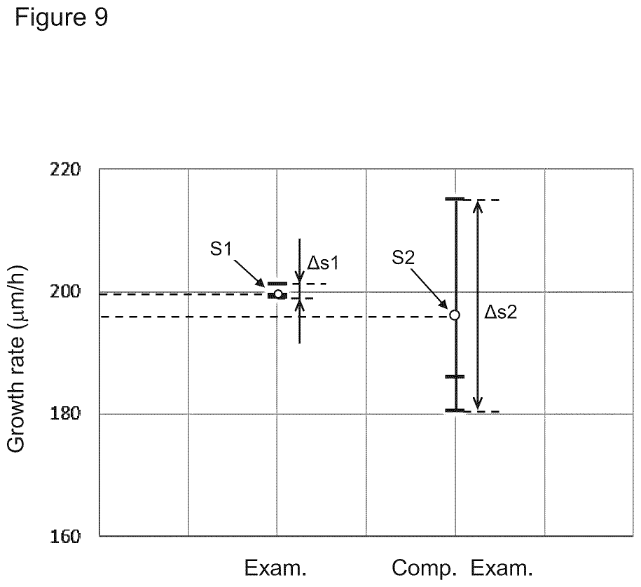

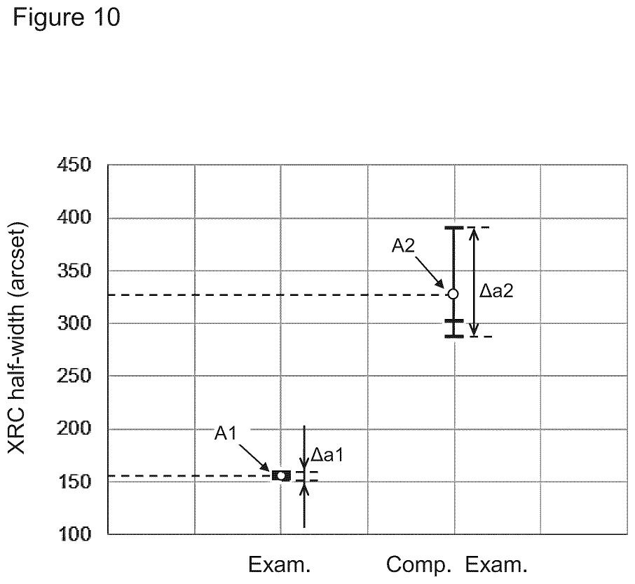

Evaluation results of the group III nitride crystal GaN obtained in Examples 1 to 3 and Comparative Examples 1 to 3 will be described with reference to FIGS. 8 to 10. FIG. 8 is a table 1 showing an evaluation of the group III nitride crystal growth in the Examples 1 to 3 and in the Comparative Examples 1 to 3 according to the embodiment of the present disclosure. FIG. 9 is a graph showing an evaluation of the growth rates of the group III nitride crystals in the Examples 1 to 3 and in the Comparative Examples 1 to 3 according to the embodiment of the present disclosure. FIG. 10 is a graph showing an evaluation of the crystallinity of the group III nitride crystals in the Examples 1 to 3 and in the Comparative Examples 1 to 3 according to the embodiment of the present disclosure.

As shown in FIGS. 8 and 9, the GaN crystals obtained in Examples 1 to 3 had an average growth rate S1 of 199.9 m/h with a maximum value of 201.2 m/h and a minimum value of 199.1 m/h, and the fluctuation range Δs1 of the growth rate was 2.1 m/h. On the other hand, the GaN crystal obtained in Comparative Examples 1 to 3 had an average growth rate S2 of 193.8 m/h with a maximum value of 215.0 m/h and a minimum value of 180.5 m/h, and the fluctuation range Δs2 of the growth rate was 34.5 μm/h. Compared with Comparative Examples 1 to 3, a more stable growth rate of the GaN crystals was confirmed in Examples 1 to 3. By introducing H₂ gas and O₂ gas separately to generate H₂O gas in the apparatus 10, H₂O gas production amount is stabilized, and the amount of the generated group III oxide gas Ga₂O gas was stabilized. This allowed the GaN crystals to be generated on the seed substrate at a stable growth rate.

Next, as shown in FIGS. 8 and 10, the crystal mosaicism of the GaN crystals was evaluated by an (0002) XRC full width at half maximum (XRC half-width in the Table 1 of FIG. 8) in an as-grown state. As a result, in Examples 1 to 3, an average value A1 of the XRC full width at half maximum was 155.3 arcsec with a maximum value of 158 arcsec and a minimum value of 153 arcsec, and the fluctuation range Δa1 of the XRC full width at half maximum was 5 arcsec. On the other hand, in Comparative Examples 1 to 3, an average value A2 of the XRC full width at half maximum was 326.3 arcsec with a maximum value of 390 arcsec and a minimum value of 287 arcsec, and the fluctuation range Δa2 of the XRC full width at half maximum was 103 arcsec. Compared with Comparative Example 1-3, The GaN crystals obtained in Examples 1 to 3 were confirmed to be more stable and have excellent crystallinity. The results indicated that when H₂ gas and O₂ gas were introduced separately to produce H₂O gas used for growing GaN crystals, the crystal mosaicism was improved and the variation was reduced, thus ensuring the stability of the quality of GaN crystals.

As above, the accompanying drawings and detailed description have been provided to describe the embodiment as an exemplification of technology disclosed herein. Therefore, the components described in the accompanying drawings and detailed description may include not only components essential for solving the problem but also components not essential for solving the problem to exemplify the above technology. Thus, describing those non-essential components in the accompanying drawings or detailed description should not be construed as immediately indicating that those non-essential components are essential.

Although the present disclosure has been fully described in relation to the preferred embodiment with reference to the accompanying drawings, various modifications are possible within the scope of the claims. Such modifications and embodiments obtained by appropriately combining the technical means disclosed in the different embodiments are also encompassed in the technical scope of the present disclosure.

The present disclosure is applicable to production of group III nitride crystals. In producing a group III nitride substrate, according to the apparatus for producing group III nitride crystals of the present disclosure, the generation amount of group III element oxide gas can be stabilized, and GaN crystals with high quality stability can be produced.

What is claimed is:

1. An apparatus for producing a group III nitride crystal, comprising:
a starting material chamber including a group III element source and the starting material chamber being configured to supply a group III element oxide gas; and
at least two gas supply pipes connected to the starting material chamber, wherein
an oxidizing gas and a reducing gas are separately supplied to the starting material chamber via the gas supply pipes and react with each other in the starting material chamber to generate a reactive gas, and
the generated reactive gas reacts with the group III element source to generate the group III element oxide gas.

2. The apparatus according to claim 1, wherein
the starting material chamber includes:
a reactive gas generation section located upstream; and
a reaction section located downstream and configured to be in fluid communication with the reactive gas generation section,
the gas supply pipes are connected to the reactive gas generation section, and
the group III element source is disposed inside the reaction section.

3. The apparatus according to claim 2, wherein
the reactive gas generation section and the reaction section are separated by a partition plate.

4. The apparatus according to claim 2, wherein
the reactive gas generation section includes at least one reflector plate.

5. The apparatus according to claim 3, wherein
the partition plate comprises at least one reflector plate.

6. The apparatus according to claim 1, wherein
the starting material chamber has a cylindrical shape with at least one connection port disposed on a side wall, and
the at least one gas supply pipe is connected to the starting material chamber via the connection port.

7. The apparatus according to claim 6, wherein
a plurality of connection ports are circumferentially arranged on the side wall with a uniform interval.

8. The apparatus according to claim 1, wherein
the starting material chamber comprises at least one material selected from a group consisting of quartz, carbon, PG, PBN, SiC, transition metal, and stainless steel.

9. The apparatus according to claim 1, wherein
the gas supply pipe comprises at least one material selected from a group consisting of quartz, carbon, PG, PBN, SiC, transition metal, and stainless steel.

10. The apparatus according to claim 2, further comprising:
a heating section, wherein
the heating section is configured to keep a temperature of the reactive gas generation section at 290° C. or higher, and to keep a temperature of the reaction section at 800° C. or higher and lower than 1800° C.

11. The apparatus according to claim 10, further comprising:
a seed substrate, wherein
a group III nitride crystal is generated on the seed substrate, and
the heating section is configured to keep a temperature of the seed substrate at a temperature higher than that of the reaction section.

12. A method for producing a group III nitride crystal, comprising:
separately supplying an oxidizing gas and a reducing gas;
generating a reactive gas by reacting the supplied oxidizing gas with the supplied reducing gas;
generating a group III element oxide gas by reacting the generated reactive gas with a group III element source; and
generating a group III nitride crystal by reacting the generated group III element oxide gas with a nitrogen element-containing gas.
